(19) United States
(12) Patent Application Publication
(10) Pub. No.: US 2024/0429068 A1
(43) Pub. Date: Dec. 26, 2024

(54) SUBSTRATE PROCESSING APPARATUS AND SUBSTRATE PROCESSING METHOD

(71) Applicant: Tokyo Electron Limited, Minato-ku, Tokyo (JP)

(72) Inventors: Yosuke KAWABUCHI, Koshi City, Kumamoto (JP); Takahiro YASUTAKE, Koshi City, Kumamoto (JP); Tsunenaga NAKASHIMA, Koshi City, Kumamoto (JP)

(21) Appl. No.: 18/690,888

(22) PCT Filed: Aug. 31, 2022
(86) PCT No.: PCT/JP2022/032814

§ 371 Date: Mar. 11, 2024

(30) Foreign Application Priority Data
Sep. 13, 2021 (JP) 2021-148495

(51) Int. Cl. H01L 21/67; B08B 5/02; H01L 21/02; H01L 21/687

(52) U.S. Cl. CPC H01L 21/67028; B08B 5/02; H01L 21/02046; H01L 21/68785

(57) ABSTRACT

A substrate processing apparatus includes: a processing container including a processing chamber; a holder configured to hold a substrate in the processing chamber; and a nozzle configured to jet a gas to irradiate a first main surface of the substrate with a gas cluster. The processing container includes an opposing wall including a first opposing surface facing the first main surface of the substrate, a plate provided on a portion of the first opposing surface, and a through-hole configured to pass through the opposing wall and the plate. The plate has a second opposing surface facing the first main surface. The through-hole is a passage of the gas and has an outlet on the second opposing surface. A first gap is formed between the opposing wall and the substrate. A second gap is formed between the plate and the substrate and is narrower than the first gap.

### TECHNICAL FIELD

The present disclosure relates to a substrate processing apparatus and a substrate processing method.

### BACKGROUND

A processing method disclosed in Patent Document 1 includes jetting a mixed gas consisting of a reactive gas (e.g., ClF₃ gas) and an additive gas (e.g., Ar gas) from a nozzle outlet to a vacuum processing chamber to generate a reactive cluster by adiabatic expansion of the mixed gas, and processing a substrate surface with the reactive cluster.

### PRIOR ART DOCUMENTS

### Patent Documents

Patent Document 1: Japanese laid-open publication No. 2013-46001

An aspect of the present disclosure provides a technique for suppressing reattachment of particles to a substrate by regulating a gas flow around the substrate.

### SUMMARY

According to an aspect of the present disclosure, a substrate processing apparatus includes a processing container including, inside the processing container, a processing chamber depressurized to a pressure lower than an atmospheric pressure, a holder configured to hold a substrate in the processing chamber, and a nozzle configured to jet a gas to irradiate a first main surface of the substrate held by the holder with a gas cluster. The processing container includes an opposing wall including a first opposing surface facing the first main surface of the substrate, a plate provided on a portion of the first opposing surface of the opposing wall, and a through-hole configured to pass through the opposing wall and the plate. The plate has a second opposing surface facing the first main surface of the substrate. The through-hole is a passage of the gas and has an outlet on the second opposing surface of the plate. A first gap is formed between the opposing wall and the substrate, a second gap is formed between the plate and the substrate. The second gap is narrower than the first gap.

According to an aspect of the present disclosure, it is possible to suppress reattachment of particles to a substrate by regulating a gas flow around the substrate.

### BRIEF DESCRIPTION OF DRAWINGS

FIG. 1 is a diagram illustrating a substrate processing apparatus according to an embodiment.

FIG. 2 is a diagram illustrating an example of movement of a holder of FIG. 1.

FIG. 3 is an enlarged diagram of a portion of FIG. 1, illustrating an example of a gas flow.

FIG. 4 is a diagram illustrating a gas flow of a substrate processing apparatus according to a reference example.

### DETAILED DESCRIPTION

Hereinafter, embodiments of the present disclosure will be described with reference to the drawings. In each drawing, the same or corresponding reference numerals may be assigned to the same or corresponding configurations, and a description thereof may be omitted.

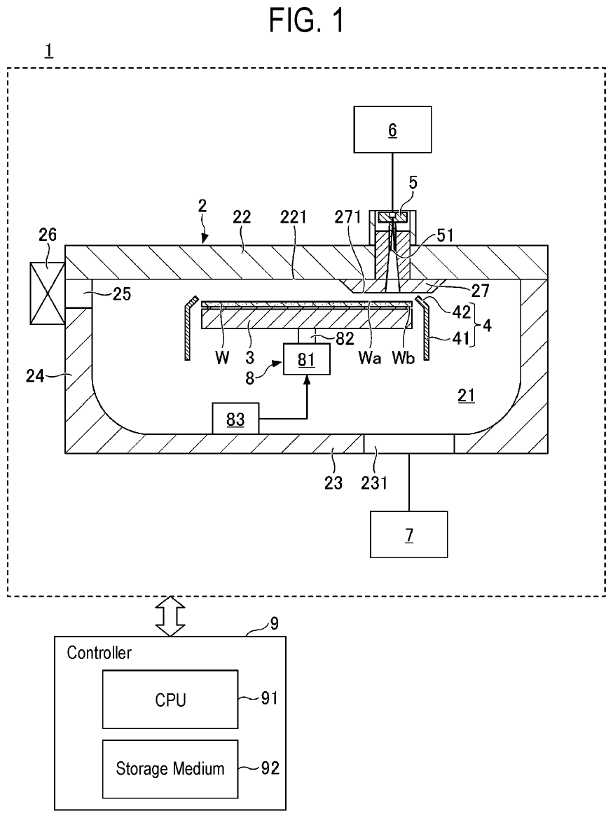

A substrate processing apparatus 1 according to an embodiment will now be described with reference to FIGS. 1 to 3. The substrate processing apparatus 1 removes particles attached to a first main surface Wa of a substrate W by irradiating the first main surface Wa of the substrate W with a gas cluster. The substrate W is, for example, a silicon wafer. The substrate W may be a compound semiconductor wafer, a sapphire substrate, or a glass substrate. The substrate W has the first main surface Wa, and a second main surface Wb opposite to the first main surface Wa. As shown in FIG. 1, the substrate processing apparatus 1 includes, for example, a processing container 2, a holder 3, a nozzle 5, a gas supplier 6, a depressurizer 7, a driver 8, and a controller 9.

The processing container 2 internally includes a processing chamber 21 that is depressurized to a pressure lower than an atmospheric pressure by the depressurizer 7. The processing container 2 has a ceiling wall 22, a bottom wall 23, and a side wall 24. The side walls 24 are formed in a frame shape. A gate 25, which is a loading/unloading port of the substrate W, is formed in the side wall 24. The gate 25 is opened and closed by a gate valve 26.

The holder 3 holds the substrate W in the processing chamber 21. The holder 3 holds the substrate W horizontally, for example, with the first main surface Wa of the substrate W facing upward. The first main surface Wa is a main surface irradiated with a gas cluster. The holder 3 holds the substrate W so that the center of the first main surface Wa coincides with the centerline of a rotary shaft 82 described later.

The nozzle 5 has an injection port 51 that injects gas in order to irradiate the substrate W held by the holder 3 with the gas cluster. The injection direction of gas is, for example, a direction perpendicular to the first main surface Wa of the substrate W, for example, a downward direction. Since the gas cluster perpendicularly collides to the first main surface Wa, pattern collapse of an uneven pattern previously formed on the first main surface Wa may be suppressed.

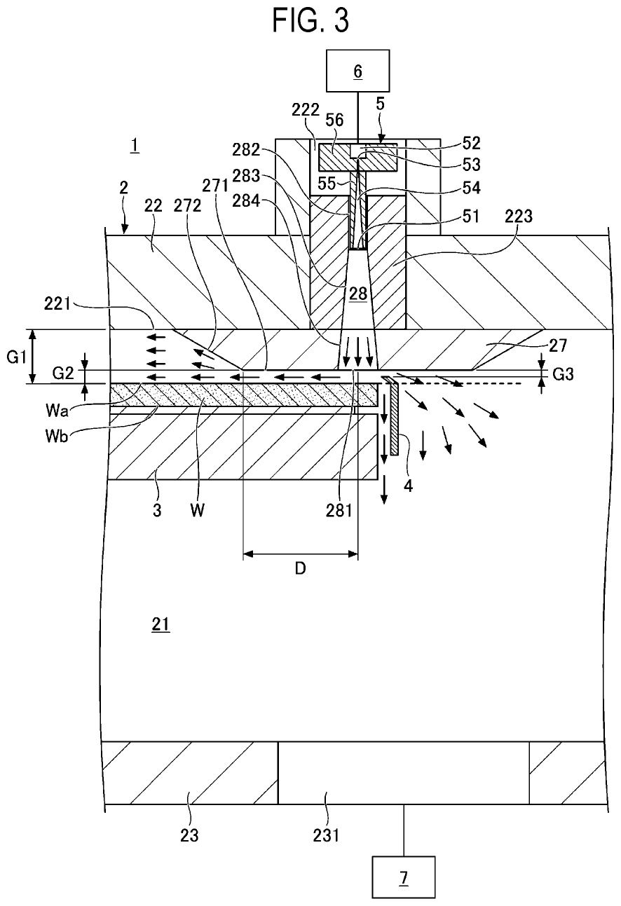

As shown in FIG. 3, the nozzle 5 has, for example, a gas supply chamber 52, a throat 53, and a tapered hole 54 in this order from an upstream side to a downstream side (e.g., from an upper side to a lower side). The tapered hole 54 has the injection port 51 at a downstream end thereof. The tapered hole 54 has a larger diameter from the upstream side toward the downstream side.

After a gas is supplied to the gas supply chamber 52, the gas is accelerated while passing through the throat 53 and is injected from the injection port 51. Since injected CO₂ gas is adiabatically expanded in the pre-depressurized processing chamber 21, the injected CO₂ gas is cooled up to a condensation temperature. This allows CO₂ molecules to bond together by van der Waals forces to form a gas cluster, which is an aggregate of the CO₂ molecules.

The gas cluster collides with particles attached to the first main surface Wa of the substrate W and blows away the particles. Even when the gas cluster collides with the first main surface Wa without directly colliding with the particles, the gas cluster may blow away the particles around a collision position. Since the gas cluster is raised to a high temperature due to collision, the gas cluster disintegrates into pieces and is exhausted from an exhaust port 231 of the bottom wall 23. The exhaust port 231 is provided, for example, at a position facing the nozzle 5, specifically, directly below the nozzle 5. The position of the exhaust port 231 is not particularly limited.

The gas supplier 6 supplies a raw material gas for forming the gas cluster to the nozzle 5. The raw material gas is injected from the nozzle 5 and adiabatically expanded in a pre-depressurized processing chamber 21 to cool the raw material gas up to a condensation temperature and to form the gas cluster, which is an aggregate of molecules or atoms. The raw material gas includes at least one gas selected from, for example, carbon dioxide (CO₂) gas or argon (Ar) gas.

The gas supplier 6 may supply a mixed gas of the raw material gas and a carrier gas to the nozzle 5. The carrier gas has a lower molecular weight or a lower atomic weight than the raw material gas. Thereby, the carrier gas has a higher condensation temperature than the raw material gas. Thus, the carrier gas does not form the gas cluster. The carrier gas includes at least one gas selected from, for example, hydrogen (H₂) gas or helium (He) gas.

The carrier gas suppresses liquefaction of the raw material gas inside the nozzle 5 by lowering the partial pressure of the raw material gas. In addition, the carrier gas increases the acceleration of the raw material gas by increasing the supply pressure of the gas to the nozzle 5 to a desired atmospheric pressure and promotes the growth of the gas cluster. In this embodiment, while the CO₂ gas is used as the raw material gas and the H₂ gas is used as the carrier gas, a combination of the gases is not particularly limited.

The size of the gas cluster may be adjusted, for example, by (A) the gas pressure of the gas supply chamber 52, (B) the flow ratio of the raw material gas to the carrier gas, and (C) the gas pressure of the processing chamber 21. If the size of the gas cluster is too small, an efficiency of particle removal is too low. In contrast, if the size of the gas cluster is too large, the uneven pattern previously formed on the first main surface Wa of the substrate W collapses.

The depressurizer 7 depressurizes the processing chamber 21 to a pressure lower than an atmospheric pressure. Although not shown, the depressurizer 7 includes, for example, a suction pump for sucking gas in the processing chamber 21, a suction line for connecting the exhaust port 231 of the bottom wall 23 and the suction pump, and a pressure controller provided in the middle of the suction line. The pressure controller adjusts the gas pressure of the processing chamber 21 under control by the controller 9. When the substrate W is irradiated with the gas cluster, the gas pressure of the processing chamber 21 is controlled, for example, to 5 Pa to 120 Pa.

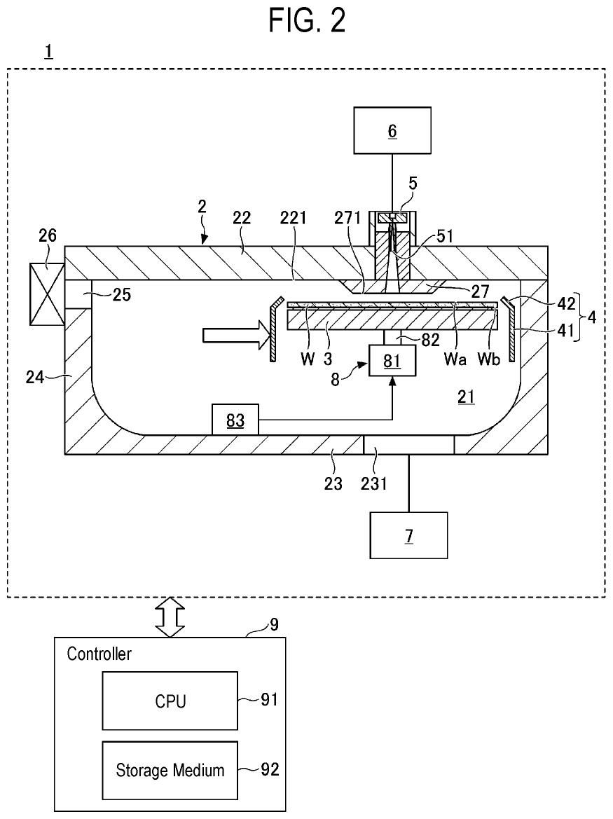

As shown in FIGS. 1 and 2, the driver 8 has a rotary driver 81 that rotates the holder 3. The holder 3 holds the substrate W so that the center of the first main surface Wa of the substrate W coincides with the centerline of the rotary shaft 82. The rotary driver 81 rotates the holder 3 around the centerline of the rotary shaft 82. Thereby, a position irradiated with the gas cluster on the first main surface Wa of the substrate W may be moved in a circumferential direction of the substrate W.

The driver 8 has a movement driver 83 that moves the holder 3. The movement driver 83 moves the holder 3 in a direction orthogonal to the centerline of the rotary shaft 82, thereby relatively moving the nozzle 5 and the holder 3 in a radial direction of the substrate W. Thereby, the position irradiated with the gas cluster on the first main surface Wa of the substrate W may be moved in the radial direction of the substrate W.

The movement driver 83 moves the holder 3 in a direction orthogonal to the centerline of the rotary shaft 82, for example, by turning an arm which is not shown. In addition, the movement driver 83 may move the holder 3 along a guide rail instead of turning the arm.

The rotary driver 81 moves the position irradiated with the gas cluster in a circumferential direction of the substrate W, and the movement driver 83 moves the position irradiated with the gas cluster in the radial direction of the substrate W. Thus, the entire first main surface Wa of the substrate W may be irradiated with the gas cluster.

In the embodiment, while the nozzle 5 is fixed to the processing container 2, the nozzle 5 may be movably provided inside the processing container 2. In this case, the position irradiated with the gas cluster on the first main surface Wa of the substrate W may be moved in the radial direction of the substrate W by moving the nozzle 5 instead of the holder 3.

The controller 9 is, for example, a computer and includes a central processing unit (CPU) 91, and a storage medium 92 such as a memory. A program for controlling various processes executed in the substrate processing apparatus 1 is stored in the storage medium 92. The controller 9 controls the operation of the substrate processing apparatus 1 by causing the CPU 91 to execute the program stored in the storage medium 92.

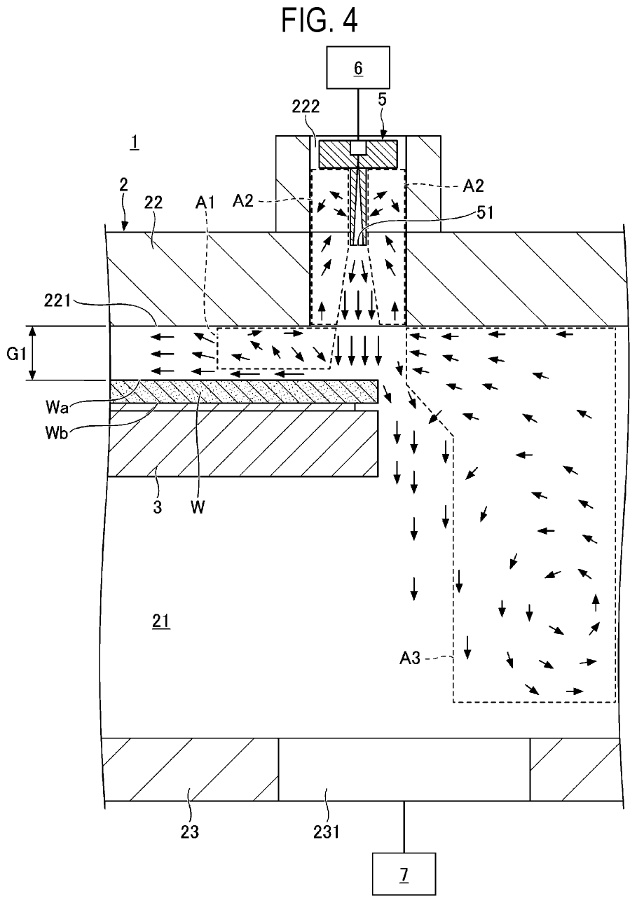

Next, problems of the substrate processing apparatus 1 according to a reference example will now be described with reference to FIG. 4. The ceiling wall 22 of the processing container 2 has a first opposing surface 221 that faces the first main surface Wa of the substrate W. The first opposing surface 221 of the ceiling wall 22 and the first main surface Wa of the substrate W are parallel and form a first gap G1. The first gap G1 is determined in consideration of workability of loading/unloading work of the substrate W.

The ceiling wall 22 has a nozzle storage 222. The nozzle storage 222 is a space for storing the nozzle 5. The nozzle 5 has, for example, a T-shaped cross-sectional shape, and the nozzle storage 222 has, for example, a rectangular cross-sectional shape. A distance between the injection port 51 of the nozzle 5 and the first main surface Wa of the substrate W is determined in consideration of the efficiency of particle removal and is adjusted as an optimum distance.

The nozzle 5 jets a gas in a direction perpendicular to the first main surface Wa of the substrate W. The gas changes direction by colliding with the first major surface Wa of the substrate W. The gas spreads radially along the first main surface Wa of the substrate W from a position at which the gas collides with the substrate W (i.e., a position irradiated with a gas cluster). When the gas flows outward from a peripheral edge of the first main surface Wa, the gas flows downward toward the exhaust port 231 of the bottom wall 23.

The problems of the substrate processing apparatus 1 according to the reference example include (1) to (3) below. (1) The size of the first gap G1 is large, and a gas flow flowing backwards toward a position irradiated with the gas cluster, as well as a gas flow flowing away from the position irradiated with the gas cluster, is formed in the first gap G1 (see dashed lines A1 in FIG. 4). The gas flow flowing backwards prevents the discharge of particles detached from the substrate W at the position irradiated with the gas cluster. As a result, the particles are reattached to the first main surface Wa of the substrate W.

(2) The size of the nozzle storage 222 is larger than the size of the nozzle 5, a surplus space exists in the nozzle storage 222, and the gas flows backwards from the outside to the inside of the nozzle storage 222 (see dashed lines A2 in FIG. 4). The gas flow that flows backwards prevents the discharge of particles detached from the substrate W. As a result, the particles are reattached to the first main surface Wa of the substrate W.

(3) A surplus space exists in the processing chamber 21, and a gas flow that winds back toward the position irradiated with the gas cluster is formed (see dashed lines A3 in FIG. 4). The gas flow that winds back prevents the discharge of particles detached from the substrate W. As a result, the particles are reattached to the first main surface Wa of the substrate W.

The problem of (3) occurs even when the nozzle 5 is not fixed and moves in the radial direction of the substrate W, but is noticeable when the nozzle 5 is fixed and the holder 3 moves. This is because the size of the processing chamber 21 is set to be large so that the holder 3 may move.

In order to solve the problem of (1) above, the processing container 2 according to the embodiment has a plate 27 provided on a portion of the first opposing surface 221 of the ceiling wall 22, and a through-hole 28 passing through the ceiling wall 22 and the plate 27, as shown in FIG. 3. Since the plate 27 is provided on a portion of the first opposing surface 221 of the ceiling wall 22, the plate 27 does not impair workability of loading/unloading work of the substrate W. Although not shown, the loading/unloading work of the substrate W is desirably performed at a position (position outside the plate 27) at which the entire substrate W, when viewed from above, does not overlap the plate 27. The plate 27 may be attachable to or detachable from the ceiling wall 22.

The plate 27 has a second opposing surface 271 facing the first main surface Wa of the substrate W. The second opposing surface 271 of the plate 27 and the first main surface Wa of the substrate W are parallel to form a second gap G2. The through-hole 28 is a passage for gas and has an outlet 281 on the second opposing surface 271 of the plate 27. The outlet 281 of the through-hole 28 faces the second gap G2. The second gap G2 is narrower than the first gap G1.

The movement driver 83 moves the holder 3 between a loading/unloading position and a processing position. The loading/unloading position is a position at which the substrate W is attached to or detached from the holder 3, and is desirably a position at which the entire substrate W, when viewed from above, does not overlap the plate 27 (a position outside the plate 27). The processing position is a position irradiated with a gas cluster on the substrate W and a position at which at least a portion of the first main surface Wa of the substrate W forms the second gap G2 with the second opposing surface 271 of the plate 27.

Since the second gap G2 is narrow, and the flow rate of gas flowing away from the position irradiated with the gas cluster is fast, a gas flow that flows backward toward the position irradiated with the gas cluster does not occur. As a result, particles detached from the substrate W at the position irradiated with the gas cluster may be quickly discharged, and reattachment of the particles to the first main surface Wa of the substrate W may be suppressed. Accordingly, the number of particles attached to the substrate W may be reduced.

The size of the second gap G2 is, for example, 20 mm or less, desirably, 15 mm or less. The size of the second gap G2 is measured in a direction orthogonal to the first main surface Wa of the substrate W. If the size of the second gap G2 is 20 mm or less, the flow rate of gas away from the position irradiated with the gas cluster is sufficiently fast. The size of the second gap G2 is desirably 1 mm or more, more desirably, 5 mm or more.

A distance D between a peripheral edge of the second opposing surface 271 and the center of the outlet 281 of the through-hole 28 is, for example, 50 mm or more, spanning the entire peripheral edge of the second opposing surface 271. If the distance D is 50 mm or more, a backward flow of gas may be suppressed around the position irradiated with the gas cluster, and reattachment of the particles may be suppressed.

The peripheral edge of the second opposing surface 271 is circular in the embodiment but may be square. The shape of the peripheral edge of the second opposing surface 271 is not particularly limited. The distance D only needs to be 50 mm or more. The distance D may be equal to or greater than a diameter (e.g., 300 mm) of the substrate W. The distance D is desirably 400 mm or less.

The plate 27 has, at a peripheral edge of the plate 27, a tapered surface 272 that approaches the first opposing surface 221 of the ceiling wall 22, as the tapered surface 272 is distant from the centerline of the through-hole 28. The tapered surface 272 is inclined with respect to the first opposing surface 221 and gradually widens a gas flow from the second gap G2 toward the first gap G1. Gas flow disruption may be suppressed by continuously varying the width of a gas flow.

In order to solve the problem of (2) above, the ceiling wall 22 of the processing container 2 according to the embodiment has a cylindrical body 223 that fills a portion of a space of the nozzle storage 222, as shown in FIG. 3. The cylindrical body 223 suppresses a backward flow of the gas from the outside to the inside of the nozzle storage 222 and suppresses reattachment of the particles.

The cylindrical body 223 regulates a gas flow from the nozzle 5 toward the substrate W by filling a portion of the space of the nozzle storage 222, thereby suppressing the spread of the gas flow and increasing the flow rate of the gas from the nozzle 5 toward the substrate W. Thereby, the gas cluster may be efficiently generated and the efficiency of particle removal is increased.

The nozzle 5 has a T-shaped cross-sectional shape and has a shaft portion 55 and a flange portion 56 larger than the shaft portion 55. The shaft portion 55 is provided, for example, vertically. The flange portion 56 is horizontally provided at an upper end of the shaft portion 55. A gas supply chamber 52 is formed on an upper surface of the flange portion 56, and an injection port 51 is formed on a lower surface of the shaft portion 55.

The cylindrical body 223 surrounds the shaft portion 55. The cylindrical body 223 is formed with, for example, a straight hole 282 into which the shaft portion 55 of the nozzle 5 is inserted, and a first tapered hole 283 extending from the straight hole 282 toward the substrate W.

The cylindrical body 223 is in contact with the plate 27. A second tapered hole 284 expanding from the first tapered hole 283 toward the substrate W is formed in the plate 27. The second tapered hole 284 is formed continuously from the first tapered hole 283. The outlet 281 of the through-hole 28 is formed at a downstream end of the second tapered hole 284.

The through-hole 28 has the straight hole 282, the first tapered hole 283, and the second tapered hole 284 in this order from an upstream side to a downstream side. The first tapered hole 283 and the second tapered hole 284 have a shape that extends the tapered hole 54 of the nozzle 5 toward a downstream side and suppress spread of a gas flow and a backward flow of gas.

In order to solve the problem of (3) above, the substrate processing apparatus 1 according to the embodiment includes a rectifying ring 4 that surrounds a peripheral edge of the substrate W held by the holder 3 and regulates a gas flow in the peripheral edge of the substrate W. The rectifying ring 4 may block a gas flow that winds back toward the peripheral edge of the substrate W, thereby suppressing reattachment of particles.

The rectifying ring 4 protrudes toward the first opposing surface 221 of the ceiling wall 22 and the second opposing surface 271 of the plate 27 more than the first main surface Wa of the substrate W. A third gap G3 is formed between a tip (e.g., an upper end) of the rectifying ring 4 and the second opposing surface 271 of the plate 27. The third gap G3 is narrower than the second gap G2.

Since the third gap G3 is narrow, and the flow rate of the gas from the peripheral edge of the substrate W toward an outward side in the radial direction of the substrate W along the second opposing surface 271 of the plate 27 is fast, there is no gas flow that winds back toward the peripheral edge of the substrate W. Thus, reattachment of particles may be suppressed. The third gap G3 may be variable. Specifically, the rectifying ring 4 may be relatively movable with respect to the holder 3 in a direction perpendicular to the first main surface Wa of the substrate W (e.g., a vertical direction).

The rectifying ring 4 forms two gas flows, for example, in a vicinity of the peripheral edge of the substrate W. One flow is a flow parallel to the second opposing surface 271 of the plate 27 and flows from the peripheral edge of the substrate W toward the outward side of the radial direction of the substrate W. Another flow is a flow perpendicular to the second opposing surface 271 of the plate 27 and flows through a gap formed between the peripheral edge of the substrate W and the rectifying ring 4 (e.g., downward flow)

As shown in FIGS. 1 and 2, the rectifying ring 4 has, for example, a vertical portion 41 perpendicular to the first main surface Wa of the substrate W and an inclined portion 42 inclined with respect to the first main surface Wa of the substrate W. The inclined portion 42 becomes away from the first opposing surface 221 of the ceiling wall 22 and the second opposing surface 271 of the plate 27 as the inclined portion 42 is toward the outward side of the radial direction of the substrate W. The inclined portion 42 may smoothly change a direction of a portion of a gas flow flowing along the second opposing surface 271 of the plate 27 to a direction away from the second opposing surface 271 of the plate 27.

The rotary driver 81 may rotate the rectifying ring 4 together with the holder 3. The substrate W held by the holder 3 and the rectifying ring 4 may be rotated in the same direction at the same rotation speed. A relative speed difference between the substrate W and the rectifying ring 4 may be reduced and bounce of particles colliding with the rectifying ring 4 may be suppressed. The particles flow along the vertical portion 41 of the rectifying ring 4 after colliding with the rectifying ring 4.

In the embodiment, while the plate 27, the cylindrical body 223, and the rectifying ring 4 are used to solve the three problems of (1) to (3) above, it is sufficient to solve one or more of the above (1) to (3), and one or more selected from the plate 27, the cylindrical body 223, or the rectifying ring 4 may be used.

In the embodiment, since the holder 3 holds the substrate W horizontally with the first main surface Wa of the substrate W facing upward, the ceiling wall 22 is an opposing wall facing the first main surface Wa of the substrate W, and the nozzle 5 is arranged above the substrate W. However, the technique of the present disclosure is not limited thereto.

For example, the holder 3 may hold the substrate W vertically with the first main surface Wa of the substrate W facing sideways. The side wall 24 may be an opposing wall facing the first main surface Wa of the substrate W, and the nozzle 5 may be arranged on the side of the substrate W.

The holder 3 may hold the substrate W horizontally with the first main surface Wa of the substrate W facing downward, the bottom wall 23 may be an opposing wall facing the first main surface Wa of the substrate W, and the nozzle 5 may be arranged below the substrate W.

While the embodiments of the substrate processing apparatus and the substrate processing method according to the present disclosure have been described above, the present disclosure is not limited to the above embodiments, etc. Various changes, modifications, substitutions, additions, deletions, and combinations are possible within the scope of the claims. These naturally fall within the technical scope of the present disclosure.

The present application claims priority based on Japanese Patent Application No. 2021-148495 filed on Sep. 13, 2021, and the entirety of Japanese Patent Application No. 2021-148495 is incorporated into this application.

### EXPLANATION OF REFERENCE NUMERALS

1: substrate processing apparatus, 2: processing container, 21: processing chamber, 22: ceiling wall (opposing wall), 221: first opposing surface, 27: plate. 28: through-hole, 3: holder, 5: nozzle, W: substrate, Wa: first main surface

1-13. (canceled)

14. A substrate processing apparatus, comprising:
a processing container including, inside the processing container, a processing chamber depressurized to a pressure lower than an atmospheric pressure;
a holder configured to hold a substrate in the processing chamber; and
a nozzle configured to jet a gas to irradiate a first main surface of the substrate held by the holder with a gas cluster,
wherein the processing container includes an opposing wall including a first opposing surface facing the first main surface of the substrate, a plate provided on a portion of the first opposing surface of the opposing wall, and a through-hole configured to pass through the opposing wall and the plate,
wherein the plate has a second opposing surface facing the first main surface of the substrate,
wherein the through-hole is a passage of the gas and has an outlet on the second opposing surface of the plate,
wherein a first gap is formed between the opposing wall and the substrate,
wherein a second gap is formed between the plate and the substrate, and
wherein the second gap is narrower than the first gap.

15. The substrate processing apparatus of claim 14, wherein a size of the second gap is 20 mm or less.

16. The substrate processing apparatus of claim 14, wherein a distance between a peripheral edge of the second opposing surface and a center of the outlet of the through-hole is 50 mm or more, spanning an entire peripheral edge of the second opposing surface.

17. The substrate processing apparatus of claim 14, wherein the plate has, at a peripheral edge of the plate, a tapered surface gradually approaching the first opposing surface of the opposing wall in a direction away from a centerline of the through-hole.

18. The substrate processing apparatus of claim 14, wherein the nozzle has a tapered hole widening from an upstream side toward a downstream side, and
wherein the through-hole has a tapered hole of a shape extending the tapered hole of the nozzle toward the downstream side.

19. The substrate processing apparatus of claim 14, further comprising a driver configured to rotate the holder.

20. The substrate processing apparatus of claim 14, further comprising a rectifying ring configured to surround a peripheral edge of the substrate held by the holder and regulate a flow of the gas in the peripheral edge of the substrate.

21. The substrate processing apparatus of claim 20, wherein a third gap is formed between the rectifying ring and the plate, and
wherein the third gap is narrower than the second gap.

22. The substrate processing apparatus of claim 20, further comprising a driver configured to rotate the rectifying ring together with the holder.

23. The substrate processing apparatus of claim 15, wherein a distance between a peripheral edge of the second opposing surface and a center of the outlet of the through-hole is 50 mm or more, spanning an entire peripheral edge of the second opposing surface.

24. The substrate processing apparatus of claim 15, wherein the plate has, at a peripheral edge of the plate, a tapered surface gradually approaching the first opposing surface of the opposing wall in a direction away from a centerline of the through-hole.

25. The substrate processing apparatus of claim 15, wherein the nozzle has a tapered hole widening from an upstream side toward a downstream side, and
wherein the through-hole has a tapered hole of a shape extending the tapered hole of the nozzle toward the downstream side.

26. The substrate processing apparatus of claim 15, further comprising a driver configured to rotate the holder.

27. The substrate processing apparatus of claim 15, further comprising a rectifying ring configured to surround a peripheral edge of the substrate held by the holder and regulate a flow of the gas in the peripheral edge of the substrate.

28. A substrate processing apparatus, comprising:
a processing container including, inside the processing container, a processing chamber depressurized to a pressure lower than an atmospheric pressure;
a holder configured to hold a substrate in the processing chamber; and
a nozzle configured to jet a gas to irradiate a first main surface of the substrate held by the holder with a gas cluster; and
a rectifying ring configured to surround a peripheral edge of the substrate held by the holder and regulate a flow of the gas in the peripheral edge of the substrate.

29. The substrate processing apparatus of claim 28, wherein the processing container has an opposing wall including a first opposing surface facing the substrate held by the holder, and
wherein a rectifying ring protrudes toward the first opposing surface of the opposing wall more than the first main surface of the substrate.

30. The substrate processing apparatus of claim 28, further comprising a driver configured to rotate the rectifying ring together with the holder.

31. A substrate processing method comprising irradiating a substrate with a gas cluster, wherein the irradiating the substrate with the gas cluster is performed by the substrate processing apparatus of claim 14.

32. A substrate processing method comprising irradiating a substrate with a gas cluster, wherein the irradiating the substrate with the gas cluster is performed by the substrate processing apparatus of claim 15.

33. A substrate processing method comprising irradiating a substrate with a gas cluster, wherein the irradiating the substrate with the gas cluster is performed by the substrate processing apparatus of claim 28.
